(19) United States
(12) Patent Application Publication
(10) Pub. No.: US 2025/0369108 A1
(43) Pub. Date: Dec. 4, 2025

(54) Substrate Processing Method and Substrate Processing Apparatus

(71) Applicant: Tokyo Electron Limited, Tokyo (JP)

(72) Inventors: Syuji NOZAWA, Yamanashi (JP); Tatsuya YAMAGUCHI, Yamanashi (JP)

(21) Appl. No.: 19/212,511

(22) Filed: May 19, 2025

(30) Foreign Application Priority Data
May 28, 2024 (JP) 2024-086412

(51) Int. Cl. C23C 16/455; C23C 16/44; C23C 16/448; C23C 16/52

(52) U.S. Cl. CPC C23C 16/45512; C23C 16/4412; C23C 16/4485; C23C 16/45561; C23C 16/52

(57) ABSTRACT

Provided a substrate processing method to be performed in a substrate processing apparatus, wherein the substrate processing apparatus includes: a processing chamber; a supply line configured to supply a mixed gas into the processing chamber; an exhaust line configured to exhaust the mixed gas; a vent line that connects the supply line and the exhaust line; and a flow rate controller having a flow rate control valve and configured to control a flow rate of the mixed gas, the substrate processing method comprising steps of: (a) supplying the mixed gas at a set flow rate to the vent line or the supply line, (b) monitoring an opening degree of the flow rate control valve, and (c) adjusting the opening degree of the flow rate control valve used for processing a substrate based on the monitored opening degree of the flow rate control valve.

### CROSS-REFERENCE TO RELATED APPLICATION

This application claims priority to Japanese Patent Application No. 2024-086412 filed on May 28, 2024, the entire contents of which are incorporated herein by reference.

### TECHNICAL FIELD

The present disclosure relates to a substrate processing method and a substrate processing apparatus.

### BACKGROUND

For example, Japanese Patent No. 6135475 discloses “outputting a control signal such that a first step of determining a flow rate of a raw material in a raw material gas based on a flow rate of a carrier gas supplied from a carrier gas supply part and a flow rate of a raw material gas detected by a flow rate detection part, and obtaining an opening degree of a flow rate control valve at which the flow rate of the raw material becomes a set value, and a second step of supplying and cutting off the supply of the raw material gas by a raw material gas supply and cut-off part in a state where the opening degree of the flow rate control valve is fixed to the acquired opening degree in order to intermittently supply the raw material gas to a film forming processing part are executed whenever a substrate to be processed is loaded into the film forming processing part.”

For example, Japanese Patent No. 5615162 discloses “a first valve controller that adjusts an opening degree of a first control valve, a second control valve provided in an inlet line, a flowmeter that measures a flow rate of a carrier gas flowing through the inlet line or a flow rate of a mixed gas flowing through an outlet line are provided, and in a first state in which the absolute value of the deviation between a measured concentration indicating value and a set value is less than or equal to a predetermined value, the opening degree of the second control valve is controlled such that the flow rate measured by the flowmeter becomes a predetermined reference value.”

### SUMMARY

The present disclosure provides a substrate processing method and a substrate processing apparatus capable of stabilizing a mixing ratio of a mixed gas used in substrate processing.

In accordance with an aspect of the present disclosure, there is provided a substrate processing method to be performed in a substrate processing apparatus, wherein the substrate processing apparatus includes: a processing chamber; a supply line configured to supply a mixed gas into the processing chamber; an exhaust line configured to exhaust the mixed gas; a vent line that connects the supply line and the exhaust line; and a flow rate controller having a flow rate control valve and configured to control a flow rate of the mixed gas, the substrate processing method comprising steps of: (a) supplying the mixed gas at a set flow rate to the vent line or the supply line, (b) monitoring an opening degree of the flow rate control valve, and (c) adjusting the opening degree of the flow rate control valve used for processing a substrate based on the monitored opening degree of the flow rate control valve.

### BRIEF DESCRIPTION OF THE DRAWINGS

FIG. 1 is a schematic diagram of a substrate processing apparatus according to one embodiment.

FIG. 2 is a schematic diagram of a flow rate controller according to one embodiment.

FIG. 3 is a diagram showing an example of a correlation graph between a flow rate of a mixed gas and an opening degree of a flow rate control valve.

FIG. 4A is a schematic diagram of a test system for supplying a mixed gas.

FIG. 4B is a diagram showing an example of a flow rate of a gas flowing into the test system.

FIG. 4C is a diagram showing an example of a correlation graph between a gas flow rate and an opening degree of a flow rate control valve.

FIG. 5 is a diagram showing an example of a correlation graph between an opening degree of a flow rate control valve and a film thickness.

FIG. 6 is a flowchart showing a substrate processing method according to one embodiment.

FIG. 7 is a schematic diagram of a substrate processing apparatus according to one embodiment.

FIG. 8A is a diagram showing an example of a film formation rate.

FIG. 8B is a diagram showing an example of an opening degree of a flow rate control valve during film formation.

### DETAILED DESCRIPTION

Hereinafter, embodiments of a substrate processing method and a substrate processing apparatus of the present disclosure will be described in detail with reference to the accompanying drawings. Further, the embodiments are not indented to limit the substrate processing method and substrate processing apparatus of the present disclosure, and the following embodiments can be appropriately combined without contradicting configurations and processing contents of the present disclosure.

Further, the drawings to be referred to below to are schematic for convenience of description. Therefore, the details thereof may be omitted, and the dimensional ratios in the drawings do not necessarily indicate the actual ratios.

### (Substrate Processing Apparatus)

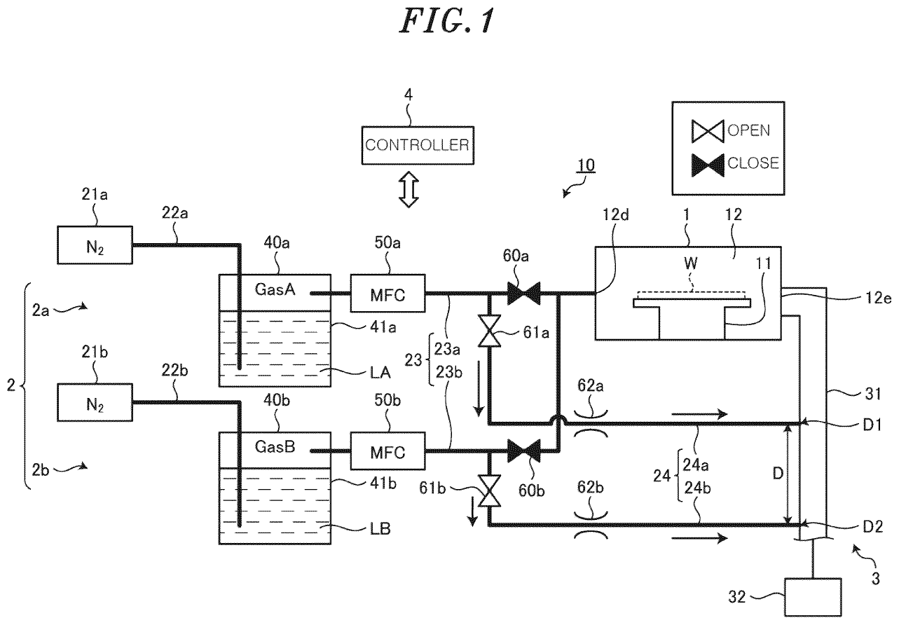

First, a configuration of a substrate processing apparatus according to an embodiment of the present disclosure will be described with reference to FIG. 1. FIG. 1 is a schematic diagram of a substrate processing apparatus according to an embodiment.

A substrate processing apparatus 10 performs processing such as film formation or the like on a substrate W. For example, the substrate processing apparatus 10 performs a film forming process for an organic film, such as polyurea, polyimide, polyamide, polyurethane, or the like, using a vapor deposition polymerization method. The substrate W may be a semiconductor wafer or a glass substrate. The film formation may be performed using a chemical vapor deposition (CVD) method, an atomic layer deposition (ALD) method, or other film forming methods. The substrate processing apparatus 10 may be a single-wafer type substrate processing apparatus or a batch type substrate processing apparatus.

The substrate processing apparatus 10 includes a processing chamber 1, a gas supply part 2, an exhaust system 3, and a controller 4. Further, the substrate processing apparatus 10 includes a substrate support 11. The substrate support 11 is located in the processing chamber 1. The substrate support 11 supports the substrate W. The processing chamber 1 has a processing space 12 defined by the ceiling wall and the sidewall of the processing chamber 1 and the substrate support 11. The processing chamber 1 is made of a conductor such as aluminum or the like, and is grounded.

The processing chamber 1 has at least one gas supply port 12d for supplying a gas to the processing space 12 and at least one gas exhaust port 12e for exhausting a gas from the plasma processing space. The gas supply port 12d is connected to the gas supply part 2. The gas exhaust port is connected to the exhaust system 3. An opening (not shown) is formed in the sidewall of the processing chamber 1 for loading a substrate W into the processing chamber 1 and unloading the substrate W from the processing chamber 1. The opening is opened and closed by a gate valve (not shown).

The gas supply part 2 has a supply line 23. The exhaust system 3 has an exhaust line 31. The supply line 23 is configured to supply a mixed gas containing two or more types of gases into the processing chamber 1. The exhaust line 31 is configured to exhaust the mixed gas. The vent line 24 connects the supply line 23 and the exhaust line 31.

The gas supply part 2 has a first gas supply part 2a and a second gas supply part 2b. The first gas supply part 2a has a first supply line 23a. The second gas supply part 2b has a second supply line 23b.

The supply line 23 is connected to a gas supply port 12d provided in the processing chamber 1. The supply line 23 includes a first supply line 23a and a second supply line 23b. The first supply line 23a is configured to supply a first mixed gas in which two or more types of gases are mixed. The second supply line 23b is configured to supply a second mixed gas in which two or more types of gases are mixed.

The vent line 24 includes a first vent line 24a and a second vent line 24b.

The first vent line 24a connects the first supply line 23a and the exhaust line 31. The second vent line 24b connects the second supply line 23b and the exhaust line 31.

The exhaust line 31 is connected to a gas exhaust port 12e provided in the processing chamber 1. The exhaust system 3 further includes an exhaust device 32. The exhaust line 31 is connected to an exhaust device 32, and is configured to exhaust a gas by the exhaust device 32. The exhaust device 32 may include a pressure control valve and a vacuum pump. The pressure control valve adjusts a pressure in the processing space 12s. The vacuum pump may include a turbo molecular pump, a dry pump, or a combination thereof.

Further, the first gas supply part 2a includes a first vaporizer 40a, a first flow rate controller 50a, a first on/off valve 60a, and a third on/off valve 61a. The first supply line 23a connects the first vaporizer 40a and the processing chamber 1. The first vaporizer 40a, the first flow rate controller 50a, and the first on/off valve 60a are provided in the first supply line 23a in that order from the upstream side. The first gas supply part 2a supplies the first mixed gas outputted from the first vaporizer 40a into the processing chamber 1. For example, the first mixed gas may be a mixed gas of a gas of a first raw material LA and N₂ gas. N₂ gas in the first mixed gas is an example of a carrier gas. The carrier gas is not limited thereto, and may be an inert gas such as He gas or the like.

The first vent line 24a branches off from the first supply line 23a between the first flow rate controller 50a and the first on/off valve 60a. A third on/off valve 61a and a first orifice 62a are provided in the first vent line 24a. The first on/off valve 60a controls start and stop of the supply of the first mixed gas from the first supply line 23a to the processing chamber 1. The third on/off valve 61a controls start and stop of the exhaust of the first mixed gas from the first vent line 24a to the exhaust line 31. The first orifice 62a is a throttle part that adjusts the flow rate of the gas flowing through the first vent line 24a.

Further, the second gas supply part 2b includes a second vaporizer 40b, a second flow rate controller 50b, a second on/off valve 60b, and a fourth on/off valve 61b. The second supply line 23b connects the second vaporizer 40b and the processing chamber 1. The second vaporizer 40b, the second flow rate controller 50b, and the second on/off valve 60b are provided in the second supply line 23b in that order from the upstream side. The second gas supply part 2b supplies the second mixed gas outputted from the second vaporizer 40b into the processing chamber 1. For example, the second mixed gas may be a mixed gas of a gas of a second raw material LB and N₂ gas. N₂ gas in the second mixed gas is an example of a carrier gas. The carrier gas is not limited thereto, and may be an inert gas such as He gas or the like.

The second vent line 24b branches off from the second supply line 23b between the second flow rate controller 50b and the second on/off valve 60b. A fourth on/off valve 61b and a second orifice 62b are provided in the second vent line 24b. The second on/off valve 60b controls start and stop of the supply of the second mixed gas from the second supply line 23b to the processing chamber 1. The fourth on/off valve 61b controls start and stop of the exhaust of the second mixed gas from the second vent line 24b to the exhaust line 31. The second orifice 62b is a throttle part that adjusts the flow rate of the gas flowing through the second vent line 24b.

The second supply line 23b is connected to the first supply line 23a at the downstream side of the first on/off valve 60a. However, the present disclosure is not limited thereto, and the second supply line 23b may be connected to a gas supply port (not shown) formed in the processing chamber 1 without being connected to the first supply line 23a.

A distance D between a connection position D1 of the first vent line 24a and the exhaust line 31 and a connection position D2 of the second vent line 24b and the exhaust line 31 is several tens of centimeters or more. Therefore, it is possible to prevent the first mixed gas exhausted from the first vent line 24a to the exhaust line 31 and the second mixed gas exhausted from the second vent line 24b to the exhaust line 31 from being mixed in the exhaust line 31, thereby avoiding the film formation in the piping.

The first carrier gas source 21a is connected to the first carrier gas supply line 22a. The first carrier gas source 21a supplies N₂ gas to the first vaporizer 40a. The second carrier gas source 21b is connected to the second carrier gas supply line 22b. The second carrier gas source 21b supplies N₂ gas to the second vaporizer 40b. The first carrier gas supply line 22a and the second carrier gas supply line 22b are also collectively referred to as the carrier gas supply line 22.

The first vaporizer 40a and the second vaporizer 40b are examples of a vaporizer configured to vaporize a raw material and generate a gas containing the vaporized raw material gas. The first vaporizer 40a and the second vaporizer 40b are also collectively referred to as the vaporizer 40.

The first vaporizer 40a has a tank 41a that contains the liquid first raw material LA. N₂ gas flows through the first carrier gas supply line 22a and is supplied to the tank 41a. The first vaporizer 40a vaporizes the first raw material LA by heating, and generates a first mixed gas consisting of the vaporized first raw material gas and N₂ gas that is a carrier gas. The first raw material LA is not limited to liquid, and may be a solid. In the example of FIG. 1, the first mixed gas is indicated as GasA.

The second vaporizer 40b has a tank 41b that contains the liquid second raw material LB. N₂ gas flows through the second carrier gas supply line 22b and is supplied to the tank 41b. The second vaporizer 40b vaporizes the second raw material LB by heating, and generates a second mixed gas consisting of the vaporized second raw material gas and N₂ gas that is a carrier gas. The second raw material LB is not limited to liquid, and may be a solid. In the example of FIG. 1, the second mixed gas is indicated as GasB.

The first flow rate controller 50a and the second flow rate controller 50b are mass flow controllers (MFC), have flow rate control valves, and are configured to monitor and control the flow rate of the gas and the current positions of the flow rate control valves. Specifically, the first flow rate controller 50a has a first flow rate control valve and monitors and controls the flow rate of the first mixed gas and the current position of the first flow rate control valve. The second flow rate controller 50b has a second flow rate control valve and monitors and controls the flow rate of the second mixed gas and the current position of the second flow rate control valve. The first flow rate controller 50a and the second flow rate controller 50b are collectively referred to as flow rate controllers 50. The gas flow rates and the current positions of the flow rate control valves monitored and controlled by the flow rate controller 50 are transmitted to the controller 4 as log information of the flow rate controller 50 and stored in the memory part of the controller 4. The internal configuration of the flow rate controller 50 will be described later.

The controller 4 processes computer-executable instructions that cause the substrate processing apparatus 10 to perform various processes included in the substrate processing method described in the present disclosure. The controller 4 may be configured to control individual components of the substrate processing apparatus 10 to perform various processes described herein. In one embodiment, the controller 4 may be partially or entirely included in the substrate processing apparatus 10. The controller 4 may include a processor, a storage device, and a communication interface. The controller 4 is realized by, for example, a computer. The processor reads a program from the storage device, and executes the read program. Accordingly, various control operations can be performed. The program may be stored in the storage device in advance, or may be acquired via a medium when necessary. The acquired program is stored in the storage device, and is read from the storage device and executed by the processor. The medium may be various computer-readable storage media, or may be a communication line connected to the communication interface. The processor may be a central processing unit (CPU). The storage device may include a random access memory (RAM), a read only memory (ROM), a hard disk drive (HDD), a solid state drive (SSD), or a combination thereof. The communication interface communicates with the substrate processing apparatus 10 via a communication line such as a local area network (LAN).

The first raw material LA and the second raw material LB are examples of the monomer of the film forming material. The first raw material LA is an example of a first monomer, and may be, for example, isocyanate. The first flow rate controller 50a controls the flow rate of the first mixed gas that is a mixed gas of the gas of the first raw material LA, which is vaporized by the first vaporizer 40a, and N₂ gas. Further, the second source LB is an example of a second monomer, and may be, for example, an amine. The second flow rate controller 50b controls the flow rate of a second mixed gas that is a mixed gas of the gas of the second raw material LB, which is vaporized by the second vaporizer 40b, and N₂ gas.

The first raw material gas, such as isocyanate, and the second raw material gas, such as amine, are examples of the film forming gas. For example, the first mixed gas containing isocyanate gas and the second mixed gas containing amine gas are mixed in the processing space 12 to form an organic film of a polymer having a urea bond on the surface of the substrate W supported by the substrate support 11.

For example, linear polyurea can be generated by using diisocyanate as the first monomer and diamine (for example, primary amine) as the second monomer. The combination of diisocyanate and diamine is, for example, the combination of 4,4′-diphenylmethane diisocyanate (MDI) and 1,12-diaminododecane (DAD). The combination of diisocyanate and diamine is, for example, the combination of 1,3-bis(isocyanatomethyl)cyclohexane (H6XDI) and 1,12-diaminododecane (DAD). The combination of diisocyanate and diamine is, for example, the combination of 1,3-bis(isocyanatomethyl)cyclohexane (H6XDI) and 1,3-bis(aminomethyl)cyclohexane (H6XDA). The combination of diisocyanate and diamine is, for example, the combination of 1,3-bis(isocyanatomethyl)cyclohexane (H6XDI) and hexamethylenediamine (HMDA). The combination of diisocyanate and diamine is, for example, the combination of m-xylylenediisocyanate (XDI) and m-xylylenediamine (XDA). The combination of diisocyanate and diamine is, for example, the combination of m-xylylene diisocyanate (XDI) and benzylamine (BA).

For example, crosslinkable polyurea can be generated by using diisocyanate as the first monomer and triamine (for example, primary amine) or tetraamine (for example, secondary amine) as the second monomer. Further, a trimer having a urea bond can be generated by using monoisocyanate as the first monomer and diamine (for example, primary amine) as the second monomer. Further, a dimer having a urea bond can be generated by using monoisocyanate as the first monomer and monoamine (for example, primary amine) as the second monomer.

### (Flow Rate Controller)

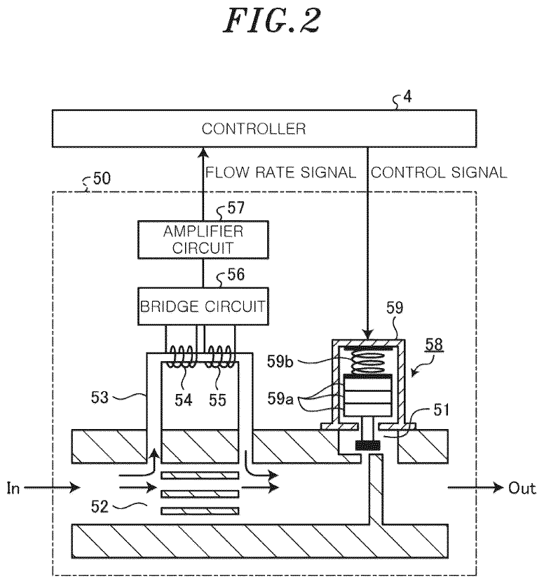

Next, the internal configuration of the flow rate controller 50 will be described with reference to FIG. 2. FIG. 2 is a schematic diagram of the flow rate controller 50 according to one embodiment. The flow rate controller 50 includes a main flow path 52, a branch flow path 53, a bridge circuit 56, and an amplifier circuit 57. The inlet and outlet of the branch flow path 53 are connected to the main flow path 52. Resistors 54 and 55 are wound around the upstream and downstream pipe walls of the branch flow path 53. The bridge circuit 56 detects the temperature change of the pipe walls of the branch flow path 53 due to the flow of the gas through the branch flow path 53 as the change in the resistance values of the resistors 54 and 55, converts it into a gas flow signal, and outputs the gas flow signal. The amplifier circuit 57 amplifies the gas flow signal and transmits it to the controller 4. The controller 4 receives the gas flow rate signal and measures the flow rate of the gas controlled by the flow rate controller 50 based on the flow rate signal.

A curved flow path 51 is connected to the main flow path 52 on the downstream side of the branch position of the branch flow path 53. The flow rate controller 50 has a flow rate control valve 58 that adjusts the flow rate of the gas flowing through the curved flow path 51. The current position of the flow rate control valve 58 is controlled by adjusting the stroke of the flow rate control valve 58 by the controller 4. Accordingly, the flow rate of the gas flowing through the curved flow path 51, i.e., the flow rate of the gas outputted from the flow rate controller 50, is controlled. The flow rate control valve 58 is operated by an actuator 59. The actuator 59 has a piezoelectric element 59a and a spring member 59b that are laminated. A valve is provided at one end of the piezoelectric element 59a, and a spring member 59b is provided at the other end thereof. The piezoelectric element 59a is fixed to the bottom portion of the flow rate control valve 58 via the spring member 59b.

The controller 4 monitors the flow rate signal, and outputs a control signal to control the flow rate control valve 58 based on the flow rate signal. The controller 4 performs feedback control of the control voltage value applied to the piezoelectric element 59a based on the control signal. Accordingly, the stroke amount of the flow rate control valve 58, i.e., the current position of the flow rate control valve 58, is adjusted. In other words, the opening degree of the flow rate control valve 58 is adjusted. For example, the controller 4 controls what percentage of the maximum voltage that can be applied to the piezoelectric element 59a will be applied to the piezoelectric element 59a as a control voltage value according to the control signal. Accordingly, the current position of the flow rate control valve 58 is determined, and the flow rate of the mixed gas flowing through the curved flow path 51 is adjusted. Hence, it is possible to adjust the flow rate of the mixed gas supplied into the processing chamber 1.

With respect to the first flow rate controller 50a, the controller 4 controls the control voltage value to be applied to the piezoelectric element 59a such that the total flow rate of the first raw material gas and N₂ gas, i.e., the flow rate of the first mixed gas, becomes the set flow rate value. Accordingly, the current position of the flow rate control valve 58 of the first flow rate controller 50a is controlled. Hence, the flow rate of the first mixed gas supplied into the processing chamber 1 can be adjusted. Further, with respect to the second flow rate controller 50b, the controller 4 controls the control voltage value applied to the piezoelectric element 59a such that the total flow rate of the second raw material gas and N₂ gas, i.e., the flow rate of the second mixed gas, becomes the set flow rate value. Accordingly, the current position of the flow rate control valve 58 of the second flow rate controller 50b is controlled. Hence, the flow rate of the second mixed gas supplied into the processing chamber 1 can be adjusted.

### (Gas Concentration)

When the first monomer and the second monomer are low vapor pressure raw materials, the low vapor pressure raw materials are unlikely to evaporate. Thus, in the case of forming a film using low vapor pressure raw materials, the vaporizer 40 is used, and a carrier gas such as N₂ gas or the like is made to flow into the vaporizer 40. Accordingly, the vaporization amount of the gas is stably supplied.

The mixed gas of the raw material gas and the carrier gas vaporized by the vaporizer 40 is supplied to the processing chamber 1 with the flow rate controlled to a constant value by the flow rate controller 50. However, due to the change in the current position of the flow rate control valve 58, the mixing ratio of the raw material gas and the carrier gas changes, which may cause the change in the concentration of the raw material gas used for film formation. As a result, the film formation rate varies, and the stability of the film formation deteriorates. For example, if the mixing ratio of the carrier gas to the raw material gas increases in a state where the flow rate of the mixed gas supplied to the processing chamber 1 is controlled to be constant, the current position of the flow rate control valve 58 changes and, thus, the film formation rate deteriorates. Hereinafter, tests 1 to 3 related to the relationship between the current position of the flow rate control valve 58 and the flow rate ratio of the carrier gas, and the relationship between the current position of the flow rate control valve 58 and the film formation will be described. Further, the current position of the flow rate control valve 58 indicates the opening degree of the flow rate control valve 58. Therefore, hereinafter, the current position of the flow rate control valve 58 will be described as the opening degree of the flow rate control valve 58.

### (Test 1)

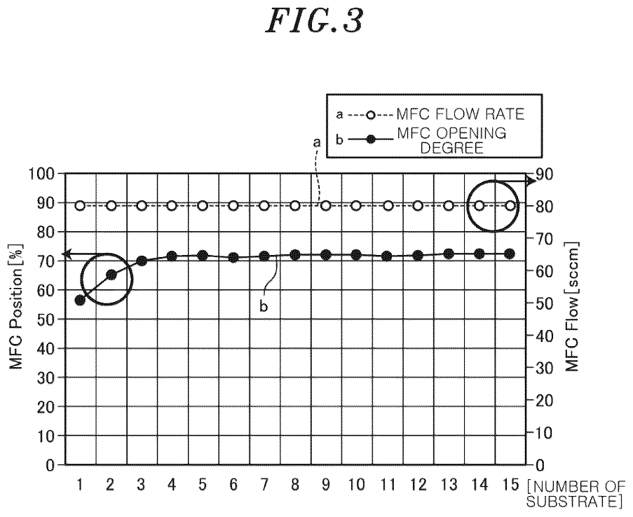

In Test 1, film formation was performed by the substrate processing apparatus 10 after four days of idle time. In Test 1, the opening degree of the flow rate control valve was measured in the case of controlling the flow rate of the mixed gas of the raw material gas and N₂ gas to be constant by the flow rate controller 50 and changing the flow rate ratio of N₂ gas to the raw material gas. The results of Test 1 will be described with reference to FIG. 3. FIG. 3 is a diagram showing an example of the correlation graph between the flow rate of the mixed gas and the opening degree of the flow rate control valve.

In the graph of FIG. 3, the horizontal axis indicates the number of substrates subjected to film formation, the left vertical axis indicates the opening degree of the flow rate control valve (MFC Position), and the right vertical axis indicates the gas flow rate value (MFC Flow). A line a indicates the flow rate value of the mixed gas controlled by the flow rate controller 50. A line b indicates the opening degree of the flow rate control valve.

As a result of Test 1, as indicated by the line a with white circles (◯), the flow rate of the mixed gas was constant while first to fifteenth substrates were being subjected to the film formation. In contrast, as indicated by the line b with black circles (●), the opening degree of the flow rate control valve was unstable while the first to third substrates were being subjected to the film formation, and was stable while the fourth to fifteenth substrates were being subjected to the film formation. In other words, in the formation of the fifteenth substrates, the flow rate of the mixed gas was stable under the control of the flow rate controller 50, but the opening degree of the flow rate control valve was not stable in the early stages of the film formation.

### (Test 2)

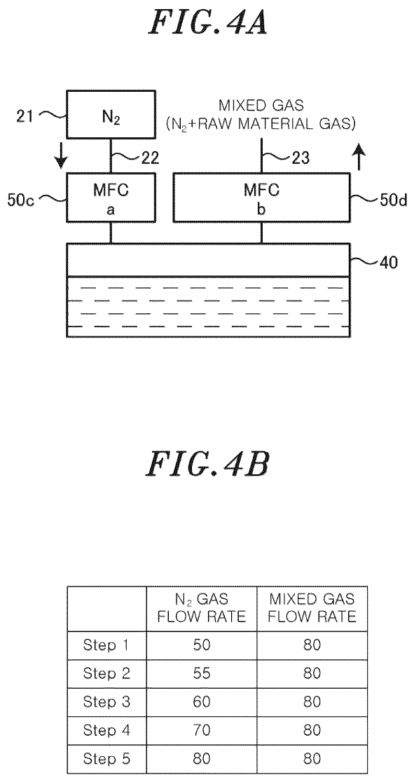

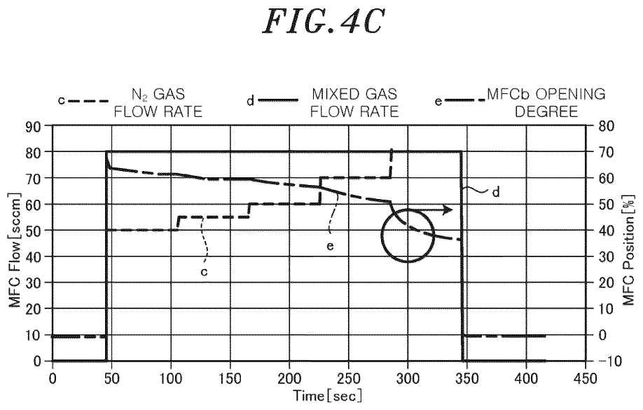

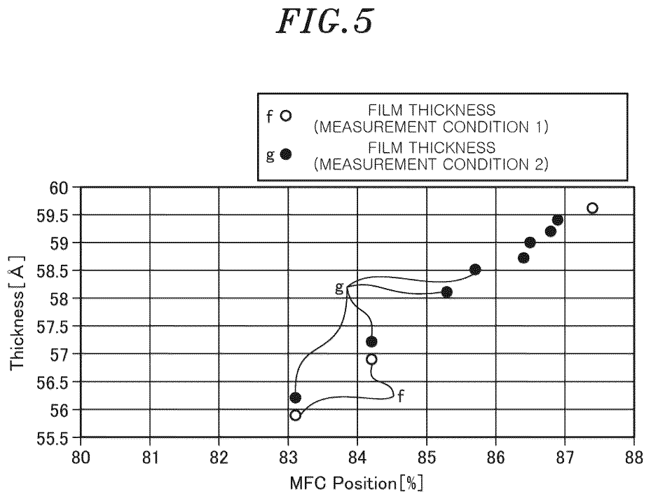

In Test 2, the opening degree of the flow rate control valve was measured in the case of controlling the flow rate of the mixed gas of the raw material gas and N₂ gas to be constant, and increasing the flow rate of N₂ gas. Test 2 will be described with reference to FIGS. 4A to 4C. FIG. 4A is a schematic diagram of a test system for supplying the mixed gas. FIG. 4B is a diagram showing an example of the flow rate of the gas flowing in the test system. FIG. 4C shows an example of the correlation graph between gas flow rate and the opening degree of the flow rate control valve.

In the test system shown in FIG. 4A, the flow rate controller (MFCa) 50c is located at the carrier gas supply line 22 connected to the carrier gas source 21 and the vaporizer 40, and controls the flow rate of N₂ gas. The flow rate controller (MFCb) 50d is located at the supply line 23 connected to the vaporizer 40, and controls the flow rate of the mixed gas of the raw material gas and N₂ gas.

As shown in FIG. 4B, the flow rate controller (MFCa) 50c increases the flow rate of N₂ gas in a stepwise manner from 50 sccm to 80 sccm in steps 1 to 5. The flow rate controller (MFCb) 50d controls the flow rate of the mixed gas of the raw material gas and N₂ gas to 80 sccm in steps 1 to 5.

In the graph of FIG. 4C, the horizontal axis indicates time, the left vertical axis indicates the gas flow rate (MFC Flow), and the right vertical axis indicates the opening degree of the flow rate control valve (MFC Position). A line c indicates the flow rate value of N₂ gas controlled by the flow rate controller (MFCa) 50c. A line d indicates the flow rate value of the mixed gas controlled by the flow rate controller (MFCb) 50d.

A line e indicates the opening degree of the flow rate control valve of the flow rate controller (MFCb) 50d. As indicated by the line e, the results of Test 2 showed that the opening degree of the flow rate control valve of the flow rate controller (MFCb) 50d changed in response to the increase in N₂ gas. This is because the pressure in the supply line 23 on the primary side (upstream side) of the flow rate controller (MFCb) 50d increased due to an increase in N₂ gas supplied to the vaporizer 40. As a result, the pressure difference between the primary side and the secondary side (downstream side) of the flow rate controller (MFCb) 50d increased and, thus, the opening degree of the flow rate control valve decreased.

### (Test 3)

In Test 3, the film thickness in the case of performing film formation on a substrate using the substrate processing apparatus 10 after one or two days of idle time was measured under different measurement conditions, and the correlation between the opening degree of the flow rate control valve and the film thickness was monitored. FIG. 5 shows an example of the correlation graph between the opening degree of the flow rate control valve and the film thickness. The case where the optical constant is fixed is set as a measurement condition 1, and the case where the optical constant is variable is set as a measurement condition 2, and the film thickness was measured under the measurement conditions 1 and 2.

In the graph of FIG. 5, the horizontal axis indicates the opening degree of the flow rate control valve (MFC position) after 100 seconds from the start of film formation, and the vertical axis indicates the film thickness (Thickness) under the measurement conditions 1 and 2 after 100 seconds from the start of film formation. The points f of the white circles (◯) indicate the film thickness under the measurement condition 1 for the opening degree of the flow rate control valve, and the points g of the black circles (●) indicate the film thickness under the measurement condition 2 for the opening degree of the flow rate control valve. In Test 3, the film thickness decreased as the opening degree of the flow rate control valve becomes smaller under both the measurement condition 1 (the points f) and the measurement condition 2 (the points g).

From the results of Tests 1 to 3, it was found that when the film formation was performed on the substrate using the substrate processing apparatus 10 after an idle time of one or two days or more, the opening degree of the flow rate control valve was not stable and decreased in the early stages of the film formation, even if the flow rate of the mixed gas was controlled to be constant. Further, as the opening degree of the flow rate control valve decreased, the film formation rate deteriorated and the film thickness decreased.

Therefore, in the embodiment of the present disclosure, a substrate processing method capable of controlling the flow rate of the mixed gas to be constant during film formation and stabilizing the mixing ratio of the raw material gas and the carrier gas is suggested.

### (Substrate Processing Method)

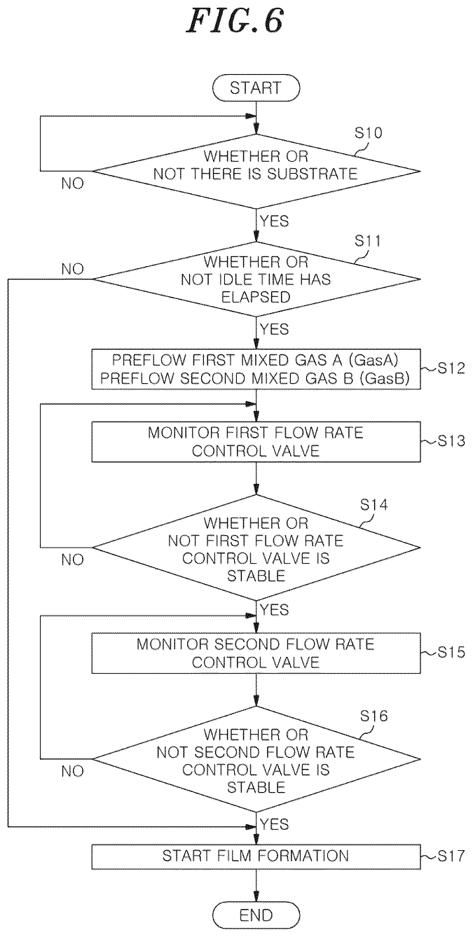

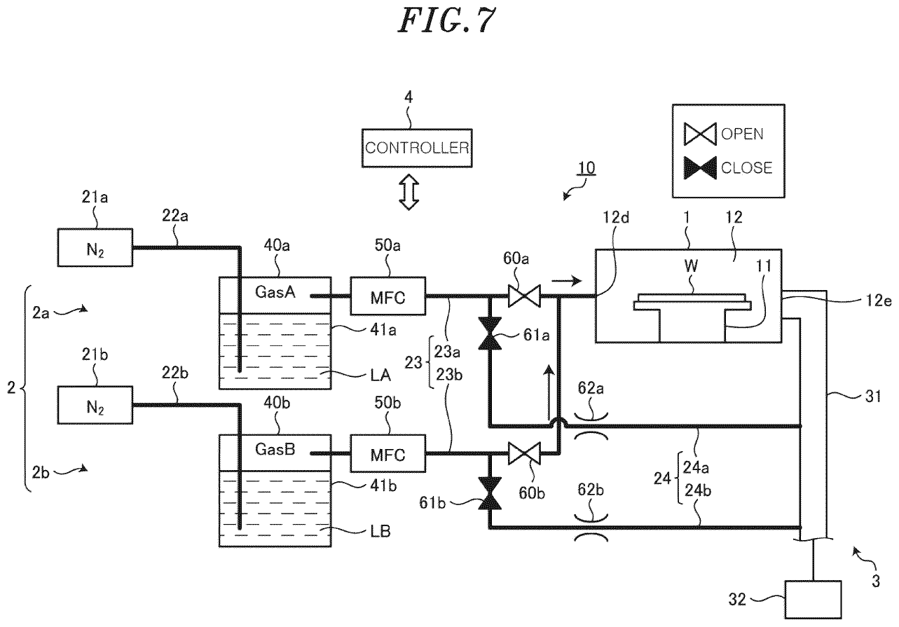

A substrate processing method according to an embodiment of the present disclosure will be described with reference to FIGS. 1, 6, and 7. FIG. 6 is a flowchart showing a substrate processing method according to an embodiment. FIGS. 1 and 7 are schematic diagrams of a substrate processing apparatus according to an embodiment. The substrate processing method is controlled by the controller 4 and performed by a substrate processing apparatus 10. Further, the substrate processing apparatus 10 is an example of a substrate processing apparatus that performs the substrate processing method according to the present disclosure, and is not limited thereto.

A first mixed gas A of a first raw material gas and N₂ gas, and a second mixed gas B of a second raw material gas and N₂ gas are used for film formation. In the substrate processing method, a mixed gas that is the same as the mixed gas used for film formation is supplied in advance to the vent line 24 or the supply line 23 before the film formation is started. Supplying the mixed gas used for film formation before the film formation is started is also referred to as “preflow.” In the substrate processing method, the film formation is started after the flow rate of the mixed gas and the opening degree of the flow rate control valve 58 are stabilized by the preflow.

First, in step S10 of FIG. 6, the controller 4 determines whether or not there is a substrate to be subjected to film formation in the substrate processing apparatus 10. If the controller 4 determines that there is a substrate to be subjected to film formation, the process proceeds to step S11.

Next, in step S11, the controller 4 determines whether or not a predetermined idle time has elapsed in the substrate processing apparatus 10. The idle time is a period of time in which film formation is continuously not performed in the substrate processing apparatus 10, and may be set to a period of time in which the vaporization amount of the raw material gas by the vaporizer 40 varies. The idle time may be set to, for example, one or two days or more. If the controller 4 determines in step S11 that the idle time has not elapsed, the process proceeds to step S17. The first mixed gas A and the second mixed gas B are supplied into the processing chamber 1, and the film formation on the substrate is started.

On the other hand, if the controller 4 determines in step S11 that the idle time has elapsed, the process proceeds to step S12, and the controller 4 supplies the first mixed gas A to the first vent line 24a (preflow). Further, the controller 4 supplies the second mixed gas B to the second vent line 24b (preflow).

As shown in FIG. 1, the flow rate of the first mixed gas A (GasA) is adjusted to a set flow rate value by the first flow rate controller 50a. Further, the flow rate of the second mixed gas B (GasB) is adjusted to a set flow rate value by the second flow rate controller 50b. In step S12, the controller 4 stabilizes the flow rate of the first mixed gas A at the set flow rate value by flowing the first mixed gas A for a predetermined period of time. Further, in step S12, the controller 4 stabilizes the flow rate of the second mixed gas B at the set flow rate value by flowing the second mixed gas B for a predetermined period of time. Step S12 is an example of the process (a).

In this case, as shown in FIG. 1, the controller 4 closes the first on/off valve 60a and the second on/off valve 60b, and opens the third on/off valve 61a and the fourth on/off valve 61b. The on/off valves shown in white indicate an open state, and the on/off valves shown in black indicate a closed state. In this state, the controller 4 exhausts the first mixed gas A from the exhaust line 31 through the first vent line 24a, and exhausts the second mixed gas B from the exhaust line 31 through the second vent line 24b. The first orifice 62a can make the conductance of the first mixed gas A on the first vent line 24a side and the processing chamber 1 side equal or close to each other. Accordingly, the pressure in the first vaporizer 40a can be stabilized, and the vaporization amount of the first raw material LA can be stabilized.

Further, the second orifice 62b can make the conductance of the second mixed gas B on the second vent line 24b side and the processing chamber 1 side equal or close to each other. Accordingly, the pressure in the second vaporizer 40b can be stabilized and, thus, the vaporization amount of the second raw material LB can be stabilized.

The controller 4 may supply the first mixed gas A to the first supply line 23a and the second mixed gas B to the second vent line 24b in a state where the third on/off valve 61a and the second on/off valve 60b are closed and the first on/off valve 60a and the fourth on/off valve 61b are opened. The controller 4 may supply the second mixed gas B to the second supply line 23b and the first mixed gas A to the first vent line 24a in a state where the first on/off valve 60a and the fourth on/off valve 61b are closed and the third on/off valve 61a and the second on/off valve 60b are opened. In this manner, one of the first mixed gas A and the second mixed gas B may be supplied to the processing chamber 1 side and the other mixed gas may be supplied to the vent line 24 side.

Next, in step S13, the controller 4 monitors the opening degree of the flow rate control valve 58 of the first flow rate controller 50a. The flow rate control valve 58 of the first flow rate controller 50a is referred to as “first flow rate control valve.” Step S13 is an example of the process (b).

Next, in step S14, the controller 4 determines whether or not the opening degree of the first flow rate control valve is stable. In an example of a method for determining whether or not the opening degree of the first flow rate control valve is stable, the opening degree of the first flow rate control valve may be determined to be stable when the monitored opening degree of the first flow rate control valve is greater than or equal to a preset first threshold value for the first flow rate control valve. For example, in the example of FIG. 3, if 71% is preset as the first threshold value for the stable opening degree of the flow rate control valve, the opening degree of the first flow rate control valve may be determined to be stable when the opening degree of the first flow rate control valve is 71% or more. Further, if 71%+3% is preset as the range of the first threshold value, the opening degree of the first flow rate control valve may be determined to be stable when the opening degree of the first flow rate control valve is 68% or more.

In another example of the method for determining whether or not the opening degree of the first flow rate control valve is stable, the opening degree of the first flow rate control valve may be determined to be stable when the variation in the monitored opening degree of the first flow rate control valve is less than or equal to a preset second threshold value for the first flow rate control valve. For example, if the second threshold value is 2%, the opening degree of the first flow rate control valve may be determined to be stable when the variation before and after the monitoring of the opening degree of the first flow rate control valve is less than or equal to 2%. The controller 4 repeats steps S13 and S14 until it is determined that the opening degree of the first flow rate control valve is stable, and proceeds to step S15 when it is determined that the opening degree of the first flow rate control valve is stable.

Next, in step S15, the controller 4 monitors the opening degree of the flow rate control valve 58 of the second flow rate controller 50b. The flow rate control valve 58 of the second flow rate controller 50b is referred to as “second flow rate control valve.” Further, step S15 is an example of the process (b).

Next, in step S16, the controller 4 determines whether or not the opening degree of the second flow rate control valve is stable. As the method for determining whether or not the opening degree of the second flow rate control valve is stable may be the same as the method for determining whether or not the opening degree of the first flow rate control valve is stable. The first threshold value for the first flow rate control valve and the first threshold value for the second flow rate control valve may be the same value or different values. Further, the second threshold value for the first flow rate control valve and the second threshold value for the second flow rate control valve may be the same value or different values.

The controller 4 repeats steps S15 and S16 until it is determined that the opening degree of the second flow rate control valve is stable, and proceeds to step S17 when it is determined that the opening degree of the second flow rate control valve is stable. Further, steps S13 to S16 (particularly S14 and S16) are an example of the process (c).

In step S17, the controller 4 starts film formation on the substrate. Step S17 is an example of the process (d). For example, as shown in FIG. 7, the controller 4 opens the first on/off valve 60a and the second on/off valve 60b, and closes the third on/off valve 61a and the fourth on/off valve 61b.

In this state, the controller 4 supplies the first mixed gas A from the first supply line 23a into the processing chamber 1. Further, the controller 4 supplies the second mixed gas B from the second supply line 23b into the processing chamber 1.

For example, the controller 4 supplies the first mixed gas A consisting of isocyanate gas and N₂ gas into the processing chamber 1. Further, the controller 4 supplies the second mixed gas B consisting of amine gas and N₂ gas into the processing chamber 1. The first mixed gas A and the second mixed gas B are mixed in the processing space 12, and an organic film of a polymer having a urea bond is formed on the surface of the substrate W. After the film is formed, the controller 4 ends this process.

Further, in FIG. 6, the processes of steps S15 and S16 are performed after the processes of steps S13 and S14. However, the present disclosure is not limited thereto. For example, the processes of steps S15 and S16 may be performed before the processes of steps S13 and S14. The processes of steps S15 and S16 may be performed in parallel with the processes of steps S13 and S14.

In accordance with the substrate processing method of the present embodiment, it is possible to stabilize the flow rate of the mixed gas and also possible to stabilize the mixing ratio of the raw material gas and the carrier gas by the preflow performed before the film formation. Accordingly, the variation in the film formation rate after the start of the film formation can be prevented, which makes it possible to improve the stability of the film formation.

### (Film Formation Results)

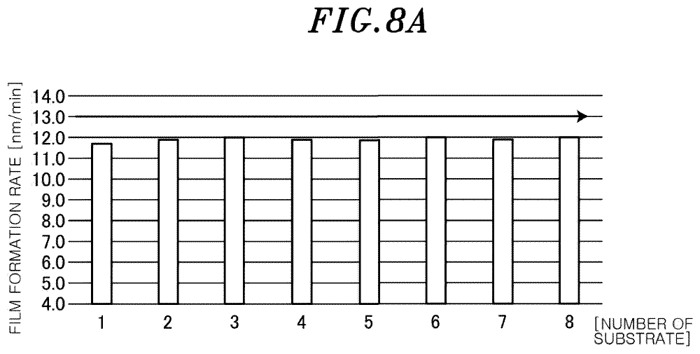

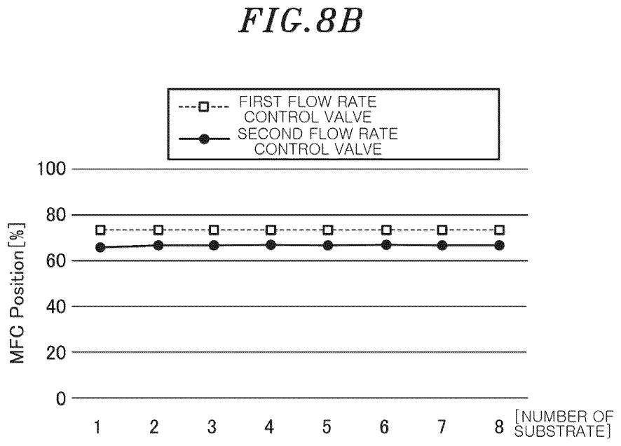

The film formation results obtained by the substrate processing method described above will be described with reference to FIGS. 8A and 8B. FIG. 8A is a diagram showing an example of the film formation rate. FIG. 8B is a diagram showing an example of the opening degree of the flow rate control valve during film formation.

FIGS. 8A and 8B show an example of the results of the film formation performed after the flow rates of the mixed gases, the opening degree of the first flow rate control valve, and the opening degree of the second flow rate control valve are stabilized by performing the preflow of the first mixed gas A and the second mixed gas B to the first vent line 24a and the second vent line 24b. In FIG. 8A, the horizontal axis indicates the number of substrates, and the vertical axis indicates the film formation rate. As shown in FIG. 8A, the film formation rate was substantially constant during the film formation of the first to eighth substrates.

Further, in FIG. 8B, the horizontal axis indicates the number of substrates, and the vertical axis indicates the opening degree of the flow rate control valve (MFC Position). As shown in FIG. 8B, the opening degree of the first flow rate control valve and the opening degree of the second flow rate control valve were substantially constant during the film formation of the first to eighth substrates.

### (Effect)

In the case of forming a film of a polymer, by using the vaporizer 40 using N₂ gas, the first mixed gas A including the first raw material gas as an example of the first monomer and N₂ gas, and the second mixed gas B including the second raw material gas as an example of the second monomer and N₂ gas are supplied to the processing space 12. Conventionally, the mixing ratio of the raw material gas and N₂ gas changes during the film formation, so that the film formation rate varies and the film formation is unstable. On the other hand, in accordance with the substrate processing method, the preflow is performed to supply the first mixed gas A and the second mixed gas B before the film formation, and the opening degree of the first flow rate control valve and the opening degree of the second flow rate control valve are monitored while stabilizing the flow rates of the first mixed gas A and the second mixed gas B. Then, the opening degrees of the first flow rate control valve and the second flow rate control valve are adjusted to be stabilized. Hence, the mixing ratio of the raw material gases of the first mixed gas A and the second mixed gas B and N₂ gas during the film formation is stabilized, and the film formation rate is stabilized, thereby improving the stability of the film formation.

According to the description of the embodiment, the substrate processing method according to the embodiment includes the processes (a), (b), and (c), as described above. In (a), the mixed gas is supplied at a set flow to the vent line or the supply line. In (b), the opening degree of the flow rate control valve is monitored. In (c), the opening degree of the flow rate control valve used for processing the substrate is adjusted based on the monitored opening degree of the flow rate control valve.

Further, the substrate processing apparatus 10 in the embodiment includes the processing chamber 1, the supply line 23, the exhaust line 31, the vent line 24, the flow rate controller 50, and the controller 4. The supply line 23 supplies the mixed gas into the processing chamber 1. The exhaust line 31 exhausts the mixed gas. The vent line 24 connects the supply line 23 and the exhaust line 31. The flow rate controller 50 has the flow rate control valve 58, and controls the flow rate of the mixed gas. The controller 4 controls the processes including (a), (b), and (c).

Further, the embodiments of the present disclosure are illustrative in all respects and are not restrictive. The above-described embodiments can be embodied in various forms. Further, the above-described embodiments may be omitted, replaced, or changed in various forms without departing from the scope of the appended claims and the gist thereof.

For example, the gas supply part 2 may be at least one of the first gas supply part 2a or the second gas supply part 2b. For example, the supply line 23 may be at least one of the first supply line 23a or the second supply line 23b. For example, the vent line 24 may be at least one of the first vent line 24a or the second vent line 24b.

Further, the following appendices are disclosed with respect to the above embodiments.

### APPENDIX 1

A substrate processing method to be performed in a substrate processing apparatus,
wherein the substrate processing apparatus includes:
a processing chamber;
a supply line configured to supply a mixed gas into the processing chamber;
an exhaust line configured to exhaust the mixed gas;
a vent line that connects the supply line and the exhaust line; and
a flow rate controller having a flow rate control valve and configured to control a flow rate of the mixed gas,
the substrate processing method comprising steps of:
(a) supplying the mixed gas at a set flow rate to the vent line or the supply line,
(b) monitoring an opening degree of the flow rate control valve, and
(c) adjusting the opening degree of the flow rate control valve used for processing a substrate based on the monitored opening degree of the flow rate control valve.

### APPENDIX 2

The substrate processing method of Appendix 1, wherein in the step (c), the opening degree of the flow rate control valve is adjusted to an opening degree when the monitored opening degree of the flow rate control valve is greater than or equal to a first threshold value, or an opening degree when the change in the monitored opening degree of the flow rate control valve is less than or equal to a second threshold value.

### APPENDIX 3

The substrate processing method of Appendix 1 or 2, further comprising a step of:
(d) starting processing of the substrate after the opening degree of the flow rate control valve is adjusted in the step (c).

### APPENDIX 4

The substrate processing method of any one of Appendices 1 to 3, wherein the substrate processing apparatus further includes:
a vaporizer connected to the supply line and configured to vaporize a raw material and generate the mixed gas containing the vaporized raw material gas,
wherein in the step (a), the mixed gas is supplied, and a conductance between the vent line and the supply line is adjusted, thereby stabilizing a pressure in the vaporizer.

### APPENDIX 5

The substrate processing method of any one of Appendices 1 to 4, wherein in the step (b), a control voltage value that is used to control an actuator that operates the flow rate control valve is monitored, and
in the step (c), the opening degree of the flow rate control valve is adjusted by controlling the control voltage value based on the monitored control voltage value.

### APPENDIX 6

The substrate processing method of any one of Appendices 1 to 5, wherein the supply line includes:
a first supply line configured to supply a first mixed gas; and
a second supply line configured to supply a second mixed gas,
the vent line includes:
a first vent line that connects the first supply line and the exhaust line; and
a second vent line that connects the second supply line and the exhaust line,
the flow rate controller includes:
a first flow rate controller having a first flow rate control valve and configured to control the flow rate of the first mixed gas; and
a second flow rate controller having a second flow rate control valve and configured to control the flow rate of the second mixed gas,
wherein in the step (a), the first mixed gas is supplied at a first set flow rate to the first vent line or the first supply line, and the second mixed gas is supplied at a second set flow rate to the second vent line or the second supply line,
in the step (b), the opening degree of the first flow rate control valve and the opening degree of the second flow rate control valve are monitored, and
in the step (c), the opening degree of the first flow rate control valve used for processing the substrate is adjusted based on the monitored opening degree of the first flow rate control valve, and the opening degree of the second flow rate control valve used for processing the substrate is adjusted based on the monitored opening degree of the second flow rate control valve.

### APPENDIX 7

A substrate processing apparatus comprising:
a processing chamber;
a supply line configured to supply a mixed gas into the processing chamber;
an exhaust line configured to exhaust the mixed gas;
a vent line that connects the supply line and the exhaust line;
a flow rate controller having a flow rate control valve and configured to control a flow rate of the mixed gas; and
a controller, wherein the controller controls processes including:
(a) supplying the mixed gas at a set flow rate to the vent line or the supply line;
(b) monitoring an opening degree of the flow rate control valve; and
(c) adjusting the opening degree of the flow rate control valve used for processing a substrate based on the monitored opening degree of the flow rate control valve.

1. A substrate processing method to be performed in a substrate processing apparatus,
wherein the substrate processing apparatus includes:
a processing chamber;
a supply line configured to supply a mixed gas into the processing chamber;
an exhaust line configured to exhaust the mixed gas;
a vent line that connects the supply line and the exhaust line; and
a flow rate controller having a flow rate control valve and configured to control a flow rate of the mixed gas,
the substrate processing method comprising steps of:
(a) supplying the mixed gas at a set flow rate to the vent line or the supply line,
(b) monitoring an opening degree of the flow rate control valve, and
(c) adjusting the opening degree of the flow rate control valve used for processing a substrate based on the monitored opening degree of the flow rate control valve.

2. The substrate processing method of claim 1, wherein in the step (c), the opening degree of the flow rate control valve is adjusted to an opening degree when the monitored opening degree of the flow rate control valve is greater than or equal to a first threshold value, or an opening degree when the change in the monitored opening degree of the flow rate control valve is less than or equal to a second threshold value.

3. The substrate processing method of claim 1, further comprising a step of:
(d) starting processing of the substrate after the opening degree of the flow rate control valve is adjusted in the step (c).

4. The substrate processing method of claim 1, wherein the substrate processing apparatus further includes:
a vaporizer connected to the supply line and configured to vaporize a raw material and generate the mixed gas containing the vaporized raw material gas,
wherein in the step (a), the mixed gas is supplied, and a conductance between the vent line and the supply line is adjusted, thereby stabilizing a pressure in the vaporizer.

5. The substrate processing method of claim 1, wherein in the step (b), a control voltage value that is used to control an actuator that operates the flow rate control valve is monitored, and
in the step (c), the opening degree of the flow rate control valve is adjusted by controlling the control voltage value based on the monitored control voltage value.

6. The substrate processing method of claim 1, wherein the supply line includes:
a first supply line configured to supply a first mixed gas; and
a second supply line configured to supply a second mixed gas,
the vent line includes:
a first vent line that connects the first supply line and the exhaust line; and
a second vent line that connects the second supply line and the exhaust line,
the flow rate controller includes:
a first flow rate controller having a first flow rate control valve and configured to control the flow rate of the first mixed gas; and
a second flow rate controller having a second flow rate control valve and configured to control the flow rate of the second mixed gas,
wherein in the step (a), the first mixed gas is supplied at a first set flow rate to the first vent line or the first supply line, and the second mixed gas is supplied at a second set flow rate to the second vent line or the second supply line,
in the step (b), the opening degree of the first flow rate control valve and the opening degree of the second flow rate control valve are monitored, and
in the step (c), the opening degree of the first flow rate control valve used for processing the substrate is adjusted based on the monitored opening degree of the first flow rate control valve, and the opening degree of the second flow rate control valve used for processing the substrate is adjusted based on the monitored opening degree of the second flow rate control valve.

7. The substrate processing method of claim 2, wherein the supply line includes:
a first supply line configured to supply a first mixed gas; and
a second supply line configured to supply a second mixed gas,
the vent line includes:
a first vent line that connects the first supply line and the exhaust line; and
a second vent line that connects the second supply line and the exhaust line,
the flow rate controller includes:
a first flow rate controller having a first flow rate control valve and configured to control the flow rate of the first mixed gas; and
a second flow rate controller having a second flow rate control valve and configured to control the flow rate of the second mixed gas,
wherein in the step (a), the first mixed gas is supplied at a first set flow rate to the first vent line or the first supply line, and the second mixed gas is supplied at a second set flow rate to the second vent line or the second supply line,
in the step (b), the opening degree of the first flow rate control valve and the opening degree of the second flow rate control valve are monitored, and
in the step (c), the opening degree of the first flow rate control valve used for processing the substrate is adjusted based on the monitored opening degree of the first flow rate control valve, and the opening degree of the second flow rate control valve used for processing the substrate is adjusted based on the monitored opening degree of the second flow rate control valve.

8. The substrate processing method of claim 3, wherein the supply line includes:
a first supply line configured to supply a first mixed gas; and
a second supply line configured to supply a second mixed gas,
the vent line includes:
a first vent line that connects the first supply line and the exhaust line; and
a second vent line that connects the second supply line and the exhaust line,
the flow rate controller includes:
a first flow rate controller having a first flow rate control valve and configured to control the flow rate of the first mixed gas; and
a second flow rate controller having a second flow rate control valve and configured to control the flow rate of the second mixed gas,
wherein in the step (a), the first mixed gas is supplied at a first set flow rate to the first vent line or the first supply line, and the second mixed gas is supplied at a second set flow rate to the second vent line or the second supply line,
in the step (b), the opening degree of the first flow rate control valve and the opening degree of the second flow rate control valve are monitored, and
in the step (c), the opening degree of the first flow rate control valve used for processing the substrate is adjusted based on the monitored opening degree of the first flow rate control valve, and the opening degree of the second flow rate control valve used for processing the substrate is adjusted based on the monitored opening degree of the second flow rate control valve.

9. A substrate processing apparatus comprising:
a processing chamber;
a supply line configured to supply a mixed gas into the processing chamber;
an exhaust line configured to exhaust the mixed gas;
a vent line that connects the supply line and the exhaust line;
a flow rate controller having a flow rate control valve and configured to control a flow rate of the mixed gas; and
a controller,
wherein the controller controls processes including:
(a) supplying the mixed gas at a set flow rate to the vent line or the supply line;
(b) monitoring an opening degree of the flow rate control valve; and
(c) adjusting the opening degree of the flow rate control valve used for processing a substrate based on the monitored opening degree of the flow rate control valve.
